(19) United States
(12) Patent Application Publication
(10) Pub. No.: US 2025/0258222 A1
(43) Pub. Date: Aug. 14, 2025

(54) PIN ELECTRONICS APPARATUS, TEST APPARATUS, AND METHOD

(71) Applicant: ADVANTEST CORPORATION, Tokyo (JP)

(72) Inventors: Takayuki TANAKA, Gunma (JP); Akira KABASAWA, Gunma (JP)

(21) Appl. No.: 19/195,693

(22) Filed: Apr. 30, 2025

Related U.S. Application Data
(63) Continuation of application No. PCT/JP2022/044927, filed on Dec. 6, 2022.

(51) Int. Cl. G01R 31/317; G01R 31/319

(52) U.S. Cl. CPC G01R 31/31721; G01R 31/31713; G01R 31/31926

(57) ABSTRACT

Provided is a pin electronics apparatus including: a test circuit which is connected to a device under test and tests the device under test; a power circuit which includes a plurality of power sources; and a monitoring circuit which records, in response to detecting an abnormality in power supply from the power circuit, power identification information for identifying a power source, for which an abnormality in power supply is detected, among the plurality of power sources on a non-volatile recording medium.

The contents of the following patent application(s) are incorporated herein by reference: NO. PCT/JP2022/044927 filed in WO on Dec. 6, 2022.

### BACKGROUND

### 1. Technical Field

The present invention relates to a pin electronics apparatus, a test apparatus, and a method.

### 2. Related Art

Patent Document 1 describes “An abnormality of an internal voltage supplied to an internal circuit of a semiconductor integrated circuit apparatus during a burn-in test can be easily confirmed” (paragraph 0010), “The semiconductor integrated circuit apparatus 100D includes internal step-down power sources 3(1), 3(2), . . . , 3(n), an abnormality detection circuit 5D, and a logic circuit 9” (paragraph 0076), and “The internal memory 10 stores information indicating the internal step-down power source 3 in which the abnormality occurs, in addition to information indicating the abnormality” (paragraph 0079).

Patent Document 2 describes “The storage element 106 is a non-volatile rewritable memory in which the stored content does not disappear even when the power supply is lost, and use of a flash memory is assumed” (paragraph 0018), and “From the operation described above, in the storage element 106 in the semiconductor integrated circuit 100 of the present invention, in the course of the operation, a duration for which the operation is performed exceeding a warning temperature is recorded as a number of unit times in the “warning temperature excess duration” region, and a temperature value when a temperature becomes the highest during the operation is recorded in the “maximum detection temperature” region. If the individual semiconductor integrated circuit 100 fails and experiences an operational failure, the control circuit 103 reads information in the “warning temperature excess duration” or “maximum detection temperature” region of the storage element 106 via the input/output unit 104″ (paragraph 0022).

Patent Document 3 describes “FIG. 1 illustrates an example of an abnormality notification system 1 of the present invention. The abnormality notification system 1 includes a bus 2, an upper module 3, and N (N is an integer of 2 or more) lower modules 4-1 to 4-N (collectively referred to as a lower module 4)” (Paragraph 0025), “Examples of the abnormality detected by the abnormality detection circuit 20 include an abnormality of a power supply voltage, an abnormality of a circuit temperature, or the like. The pin electronics card as the lower module 4 includes a power source and a circuit (for example, a field programmable gate array (FPGA)) for performing a test. The abnormality detection circuit 20 performs abnormality detection when the output voltage of the power source becomes abnormal, when the temperature of the circuit becomes abnormal, or the like” (Paragraph 0033), and “The abnormality information storage unit 22 is connected to the M abnormality detection circuits 20, and abnormality detection information indicating that the abnormality detection circuit 20 has detected an abnormality is input thereto. The abnormality detection information is 1-bit information, and the abnormality detection information is M bits in total. The M-bit abnormality detection information is stored as abnormality information in the abnormality information storage unit 22” (paragraph 0035).

Patent Document 4 describes “The circuit pack self-test system 10 (test system 10 herein), which is located on the circuit pack 18, consists of a microprocessor 20, a non-volatile memory 30 (NVM 30 herein), a volatile memory 42, a circuit under test 52 (on the circuit pack 18), and an interface circuit 60” (paragraph 0019), and “For example, when a specific test program cannot be completed due to a failure or error, this fault situation is immediately recorded in the non-volatile memory 30 to make this information available to repair personnel. This information is not lost in a power outage or power reset and is permanent in nature” (paragraph 0035).

Patent Document 5 discloses “According to the present invention, provided is an abnormality processing apparatus of an IC test apparatus in which when an abnormality which may develop into a fire occurs in the IC test apparatus, an abnormality sensor operates, an output of an abnormality monitoring circuit which has processed an detection output of the abnormality causes an interrupt in a control computer, and the control computer displays a factor of the abnormality on a terminal and operates a power control circuit to cut off power sources of the IC test apparatus and a control apparatus thereof, the abnormality processing apparatus including: various abnormality sensors of the IC test apparatus and the control apparatus which are classified according to a type of the abnormality factor; an abnormality monitoring circuit which processes the abnormality detection output and causes an interrupt in the control computer; an uninterruptible power supply apparatus which monitors an abnormality of supply power of the control apparatus, and when the abnormality occurs, supplies power to the control apparatus for a predetermined duration and notifies the abnormality monitoring circuit whether or not the control apparatus is in operation; a control computer which reads, from an abnormality monitoring circuit, an abnormality factor and whether the uninterruptible power supply apparatus is in operation and determines whether or not the IC test apparatus can be restored to an operating state; and a means in which an output of the control computer operates a power control circuit to cut off only the power source of the IC test apparatus while the power source of the control apparatus remains in an operating state and to start the power source of the IC test apparatus from a stop state” (paragraph 0009).

Patent Document 6 describes “FIG. 1 illustrates a semiconductor test apparatus 1 of the present invention. The semiconductor test apparatus 1 includes cards 2A to 2F (collectively referred to as a card(s) 2), a tester controller 3, a hard disk 4, and a connection path 5” (paragraph 0030), “The diagnosis unit 11 is provided in each card 2. The diagnosis unit 11 diagnoses whether or not a failure has occurred in its own card 2 (self-diagnosis) or diagnoses whether or not a failure has occurred in the connection path 5 as a connection unit to which the diagnosis unit 11 is connected (connection diagnosis)” (paragraph 0035), and “The diagnostic data storage unit 25 stores diagnostic data generated by the diagnostic data generation unit 24 as illustrated in FIG. 4” (paragraph 0055).

Patent Document 7 describes “The semiconductor test apparatus applies a signal to the DUT, and makes determination by comparing an output signal from the DUT and an expected value to judge whether the DUT is a non-defective product or a defective product” (paragraph 0002), and “As a result, when a failure (fail) has occurred in the diagnosis of the fail memory unit 51, information on the failure region is stored in the information storage unit 61 of the address transfer unit, and an offset address is set in the offset setting unit 63” (paragraph 0042).

### PRIOR ART DOCUMENTS

### Patent Documents

Patent Document 1: Japanese Patent Application Publication No. 2021-052122
Patent Document 2: Japanese Patent Application Publication No. 2014-003078
Patent Document 3: Japanese Patent Application Publication No. 2012-063837
Patent Document 4: Japanese Patent Application Publication No. 2000-221238
Patent Document 5: Japanese Patent Application Publication No. H7-074224
Patent Document 6: Japanese Patent Application Publication No. 2012-117932
Patent Document 7: Japanese Patent Application Publication No. 2009-020934

### BRIEF DESCRIPTION OF THE DRAWINGS

FIG. 1 illustrates a configuration of a test apparatus 1 according to the present embodiment.

FIG. 2 illustrates a configuration of a pin electronics apparatus 110 according to the present embodiment.

FIG. 3 illustrates a power monitoring flow of the pin electronics apparatus 110 according to the present embodiment.

FIG. 4 illustrates a failure monitoring flow of the pin electronics apparatus 110 according to the present embodiment.

FIG. 5 illustrates a structure of a test head 100 according to the present embodiment as viewed from a mounting surface side of a connection apparatus 120.

FIG. 6 illustrates a structure of a pin electronics apparatus 610 according to a first modification.

FIG. 7 illustrates a structure of a pin electronics apparatus 710 according to a second modification.

FIG. 8 illustrates a structure of a pin electronics apparatus 810 according to a third modification.

FIG. 9 illustrates an example of a computer 2200 in which a plurality of aspects of the present invention may be embodied entirely or partially.

### DESCRIPTION OF EXEMPLARY EMBODIMENTS

Hereinafter, the present invention will be described through embodiments of the invention, but the following embodiments do not limit the invention according to claims. In addition, not all combinations of features described in the embodiments are essential to a solution of the invention.

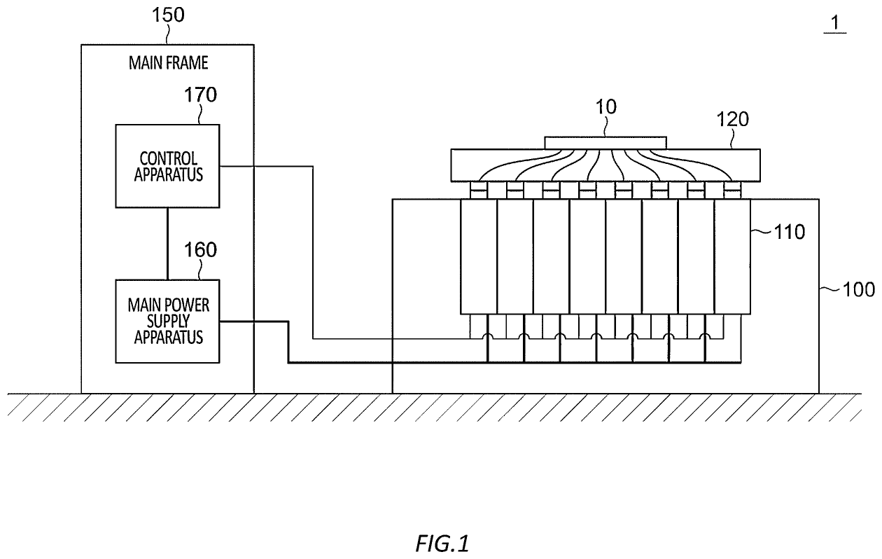

FIG. 1 illustrates a configuration of a test apparatus 1 according to the present embodiment together with a device under test (DUT) 10. The DUT 10 is a device in which a circuit to be tested by the test apparatus 1 is formed. The DUT 10 may be a wafer on which a circuit is formed, IC/LSI chips which are singulated from a wafer, an IC/LSI package in which IC/LSI chips are packaged, or the like. In the example of this drawing, the test apparatus 1 is mounted with one DUT 10, but instead of this, the test apparatus 1 may be mounted with a plurality of DUTs 10 and perform tests simultaneously.

The test apparatus 1 performs an electrical test on the DUT 10. Alternatively or additionally, the test apparatus 1 may perform a light input/output test on the DUT 10. In the present embodiment, a case where the test apparatus 1 performs the electrical test on the DUT 10 will be described as an example. When the test apparatus 1 performs the light input/output test on the DUT 10, the test apparatus 1 and the DUT 10 are connected by optical connection instead of electrical connection.

The test apparatus 1 includes a test head 100, a plurality of pin electronics apparatuses 110, a connection apparatus 120, and a main frame 150. The test head 100 is a housing on which the plurality of pin electronics apparatuses 110 can be mounted. In an example of this drawing, the test head 100 includes a plurality of slots for inserting the plurality of pin electronics apparatuses 110.

The plurality of pin electronics apparatuses 110 are inserted into the slots in the test head 100, respectively, and detachably connected to a backplane of the test head 100. The pin electronics apparatus 110 may also be referred to as a “pin electronics card,” a “tester board,” a “test module,” or the like. Each pin electronics apparatus 110 is electrically connected to the DUT 10 via the connection apparatus 120. Each pin electronics apparatus 110 inputs and outputs a signal to and from the DUT 10, and tests the DUT 10 by inspecting the signal input from the DUT 10.

The connection apparatus 120 is mounted on the test head 100 and is electrically connected to the plurality of pin electronics apparatuses 110. The connection apparatus 120 is mounted with the DUT 10 and is electrically connected to a plurality of terminals included in the DUT 10. The connection apparatus 120 serves as an interface between terminals of the plurality of pin electronics apparatuses 110 and the terminals of the DUT 10, and electrically connects each terminal of one or more DUTs 10 and the corresponding terminal of the plurality of pin electronics apparatuses 110 by a signal cable, a board wiring, or the like.

The main frame 150 controls each unit in the test apparatus 1 in order to test the DUT 10. In the present embodiment, the main frame 150 is a housing separate from a housing in which the test head 100 or the like are provided. Alternatively, each configuration in the main frame 150 may be provided in a same housing as that of the test head 100. The main frame 150 includes a main power supply apparatus 160 and a control apparatus 170.

The main power supply apparatus 160 receives power supply from a commercial power source or the like, and supplies power to each apparatus, each circuit, and the like in the test apparatus 1. The control apparatus 170 is connected to the main power supply apparatus 160 and receives power supply from the main power supply apparatus 160. The control apparatus 170 controls a test of the DUT 10. When implemented by a computer, the control apparatus 170 may control the test of the DUT 10 by executing a test control program. The control apparatus 170 supplies a test program to each pin electronics apparatus 110 and causes each pin electronics apparatus 110 to execute the test program to test the DUT 10. The control apparatus 170 collects a test result of the DUT 10 from each pin electronics apparatus 110 and records the test result.

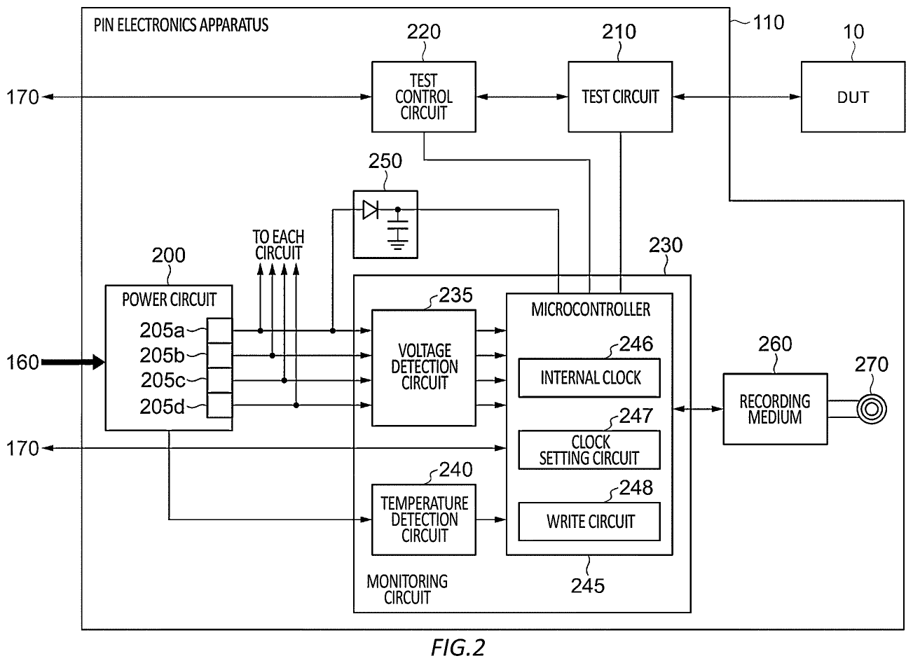

FIG. 2 illustrates a configuration of the pin electronics apparatus 110 according to the present embodiment. The pin electronics apparatus 110 includes a power circuit 200, a test circuit 210, a test control circuit 220, a monitoring circuit 230, a storage battery 250, a recording medium 260, and an antenna 270.

The power circuit 200 receives power supply from the main power supply apparatus 160, generates power to be supplied to each circuit in the pin electronics apparatus 110, and supplies the power to each circuit in the pin electronics apparatus 110. The power circuit 200 may include a plurality of power sources 205a to 205d (also referred to as a “power source(s) 205”). The plurality of power sources 205 may output power having different rated voltages, rated currents, or the like. In addition, when the pin electronics apparatus 110 uses a large amount of power having a same rated voltage, a same rated current, or the like, two or more power sources 205 may output the power having the same rated voltage, the same rated current, or the like.

The test circuit 210 is connected to the DUT 10 via the connection apparatus 120 and tests the DUT 10. The test circuit 210 for an operation test of the DUT 10 may include various circuits for determining a quality of the DUT 10 by transmitting and receiving a signal to and from the DUT 10, various circuits including at least one of a pattern generator which generates a test pattern, a timing generator which generates a timing, a waveform shaper which shapes the test pattern by using the timing generated by the timing generator and outputs a test signal, a driver circuit which amplifies the test signal and outputs a result to the DUT 10, a comparator which compares a response signal from the DUT 10 with a target value, or a determiner which determines the quality of the DUT 10 by using a result of comparison by the comparator. In addition, the test circuit 210 for a parametric test of the DUT 10 may include various circuits including at least one of a voltage generator which generates a voltage to be supplied to the DUT 10, a current generator which generates a current to be supplied to the DUT 10, a voltage measurer which measures a voltage output by the DUT 10, a current measurer which measures a current output by the DUT 10, a frequency measurer which measures a frequency of a signal output by the DUT 10, or the like. The test control circuit 220 controls the test of the DUT 10 performed by the test circuit 210. The test control circuit 220 may also be referred to as a “site controller”. The test control circuit 220 executes a test program supplied from the control apparatus 170 to control each unit in the test circuit 210, thereby causing the test circuit 210 to execute a test such as the operation test or the parametric test of the DUT 10.

The monitoring circuit 230 is connected to the power circuit 200, the test circuit 210, and the test control circuit 220. The monitoring circuit 230 monitors each component including each electronic device (ASIC, LSI, IC, or the like), each circuit, discrete components, mechanical components, and the like in the pin electronics apparatus 110, such as the power circuit 200, the test circuit 210, and the test control circuit 220 in the pin electronics apparatus 110. In response to detecting a failure of the pin electronics apparatus 110, the monitoring circuit 230 records failure information regarding the failure on the recording medium 260. In response to detecting a failure of the power circuit 200, that is, an abnormality in the power supply from the power circuit 200, the monitoring circuit 230 records, on the recording medium 260, failure information including power identification information before power supply to the monitoring circuit 230 is cut off. Here, the monitoring circuit 230 records, on the recording medium 260, the failure information including the power identification information for identifying the power source 205, for which the abnormality in power supply has been detected, among the plurality of power sources 205.

Note that, in the present specification, the “abnormality in power supply” can include both a case where an output of the power circuit 200 (or each power source 205) does not satisfy a power specification (a voltage specification, a current specification, or the like) and a case where a temperature of the power circuit 200 (or each power source 205) does not satisfy a temperature specification (an upper limit temperature or the like).

The monitoring circuit 230 includes a voltage detection circuit 235, a temperature detection circuit 240, and a microcontroller 245. The voltage detection circuit 235 is connected to each of the plurality of power sources 205. For each power source 205 of the plurality of power sources 205a to 205d, the voltage detection circuit 235 detects whether or not an output voltage of the power source 205 is outside a reference voltage range predetermined for each power source 205. The voltage detection circuit 235 may include a comparison circuit which compares the output voltage of the power source 205 with each of a rated upper limit voltage and a rated lower limit voltage of the output voltage of the power source 205. The voltage detection circuit 235 may detect an abnormality of the power source 205 when the output voltage of the power source 205 is outside the reference voltage range from the rated lower limit voltage to the rated upper limit voltage.

The temperature detection circuit 240 is connected to the power circuit 200. The temperature detection circuit 240 detects whether or not a temperature associated with each power source 205 exceeds a predetermined reference temperature. The temperature detection circuit 240 may detect the abnormality of the power source 205 when a temperature indicated by a temperature detection signal from a temperature sensor such as a thermal diode provided in a vicinity of each power source 205 exceeds a rated upper limit temperature.

In addition, the temperature detection circuit 240 may detect whether or not a temperature of each component in the pin electronics apparatus 110 exceeds a predetermined reference temperature. Such a reference temperature may be individually determined for each component, or may be commonly determined for two or more components.

The microcontroller 245 is connected to each circuit or component to be monitored, such as the power circuit 200, the test circuit 210, and the test control circuit 220, the voltage detection circuit 235, and the temperature detection circuit 240. The microcontroller 245 may include a central processing unit (CPU) for control or general purpose. The microcontroller 245 executes a monitoring program to monitor (including temperature monitoring) a failure of each component in the pin electronics apparatus 110, monitor the plurality of power sources 205, and write the failure information to the recording medium 260.

The microcontroller 245 includes an internal clock 246, a clock setting circuit 247, and a write circuit 248. The internal clock 246 outputs a current date and time. For example, the internal clock 246 may indicate the current time by being set to a certain date and time and updating an internal time every time a predetermined duration elapses from the date and time. In addition, the internal clock 246 may include a timer counter which is reset to a certain date and time and increments each time a predetermined duration elapses, and may calculate the current date and time by using an elapsed duration from the reset date and time indicated by the timer counter.

The clock setting circuit 247 sets, in internal clock 246, the current date and time received from an apparatus external to the pin electronics apparatus 110. The clock setting circuit 247 may receive writing of the current date and time from the control apparatus 170 at a time of activation of the test apparatus 1 or periodically and set the current date and time. Note that, when the microcontroller 245 does not record a failure detection date and time on the recording medium 260 in association with the failure information, the microcontroller may not include the internal clock 246 and the clock setting circuit 247.

In response to detecting the failure of the pin electronics apparatus 110, the write circuit 248 records, on the recording medium 260, the failure information regarding the failure. In response to the voltage detection circuit 235 or the temperature detection circuit 240 detecting the abnormality in the power supply from the power circuit 200, the write circuit 248 records the failure information on the recording medium 260, the failure information including the power identification information for identifying the power source 205 for which the abnormality is detected. In addition, in response to detecting a failure of the test circuit 210, the test control circuit 220, or another component of the pin electronics apparatus 110, the write circuit 248 records, on the recording medium 260, the failure information including component identification information for identifying a failed component.

Note that the monitoring circuit 230 may include, instead of the microcontroller 245, dedicated hardware which implements, by a dedicated circuit, an operation to be performed by the microcontroller 245. In addition, the monitoring circuit 230 may perform only one or two of failure detection of each component in the pin electronics apparatus 110, failure detection of each power source 205 by the voltage detection circuit 235, or failure detection of each power source 205 by the temperature detection circuit 240. The monitoring circuit 230 may not include the voltage detection circuit 235 when the failure detection of each power source 205 by the voltage detection circuit 235 is not performed, and may not include the temperature detection circuit 240 when the failure detection of each power source 205 by the temperature detection circuit 240 is not performed.

The storage battery 250 is connected to the power circuit 200. The storage battery 250 accumulates power from at least one of the plurality of power sources 205. The storage battery 250 may include a capacitor which accumulates power, and may include a small capacity battery which can be charged.

The storage battery 250 may accumulate power from the power source 205, which supplies power to the monitoring circuit 230, among the plurality of power sources 205 and provide the power to the monitoring circuit 230. Accordingly, the monitoring circuit 230 can record the power identification information on the non-volatile recording medium 260 after the power supply from the power circuit 200 is cut off and before the power supply from the storage battery 250 is interrupted.

The recording medium 260 is connected to the monitoring circuit 230. The recording medium 260 receives a write request of the failure information from the monitoring circuit 230 and stores the failure information. The recording medium 260 may be capable of storing one set of failure information or may be capable of storing a plurality of sets of failure information. The recording medium 260 may be a non-volatile recording medium such as a flash memory, so that the stored failure information is not lost even after the power supply from the power circuit 200 is cut off.

In addition, the recording medium 260 may be a recording medium which is readable without receiving power supply from a power source, such as the power circuit 200, provided in the pin electronics apparatus 110. For example, the recording medium 260 may be implemented by using an RFID or the like which is connected to the antenna 270 and is readable by near field communication. The antenna 270 is used to access information (data) recorded on the recording medium 260 by near field communication. The antenna 270 may receive, by wireless power supply from an external terminal or the like, power for operating the recording medium 260, supply the power to the recording medium 260, and operate the recording medium 260 by the power. Then, the antenna 270 supplies, to the recording medium 260, a read request from an external terminal or the like according to a protocol of near field communication, and returns, to the external terminal or the like, information read from the recording medium 260.

Note that the recording medium 260 may be built in the monitoring circuit 230. In addition, the microcontroller 245 may use, as recording medium 260, at least a partial region of a non-volatile memory built in the microcontroller 245.

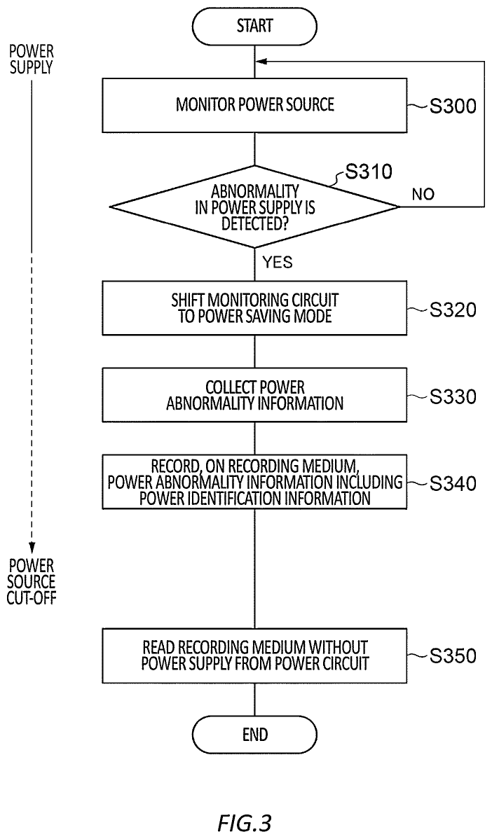

FIG. 3 illustrates a power monitoring flow of the pin electronics apparatus 110 according to the present embodiment. The pin electronics apparatus 110 starts the power monitoring flow of this drawing in a state where the power circuit 200 is normally supplying power to each circuit in the pin electronics apparatus 110.

In S300, the microcontroller 245 in the monitoring circuit 230 monitors the state of the power circuit 200. In S310, the microcontroller 245 determines whether or not the abnormality in the power supply by the power circuit 200 is detected. In response to output voltage of each power source 205 becoming outside the reference voltage range defined for the power source 205 or the temperature of each power source 205 exceeding the reference temperature defined for the power source 205, the microcontroller 245 detects the abnormality of the power source 205. The microcontroller 245 acquires, as the failure detection date and time, date and time which are indicated by the internal clock 246 at a timing when the abnormality in power supply is detected.

If the power supply is normal, the microcontroller 245 advances the processing to S300 to continue monitoring the state of the power circuit 200 (“NO” in S310). If the power supply is abnormal, the microcontroller 245 advances the processing to S320 (“YES” in S310).

In S320, in response to cut-off of the power supply from the power circuit 200 and reception of the power supply from the storage battery 250, the monitoring circuit 230 shifts to a power saving mode in which a power consumption is smaller than that in a case of performing a normal operation. For example, the monitoring circuit 230 may reduce the power consumption, for example, by stopping power supply to at least one of the voltage detection circuit 235 or the temperature detection circuit 240, by shifting the microcontroller 245 to the power saving mode to cut off power supply to some circuits in the microcontroller 245, or by reducing an operating frequency of the microcontroller 245. Note that even in a normal operation mode, the monitoring circuit 230 may not execute S320 when the failure information can be written to the recording medium 260 until the power supply to the monitoring circuit 230 is cut off after the power supply from the power circuit 200 is cut off.

In S330, the monitoring circuit 230 collects power abnormality information used as the failure information in a case of power abnormality. The power abnormality information as the failure information may include the power identification information as the component identification information, and may include failure type information indicating a type of failure, detailed component information (a product model number, a serial number, a date of manufacture, a manufacturer, or the like) of a failed component (the power circuit 200, the power source 205, or the like), or various types of information regarding a failure in the output voltage of each power source 205 measured by the voltage detection circuit 235 or the power source 205 in which a failure has occurred, the temperature of each power source 205 detected by the temperature detection circuit 240 or the power source 205 in which a failure has occurred, or the like. Note that the component identification information may include more detailed information including at least one of the product model number, the serial number, the date of manufacture, the manufacturer, or the like, in addition to information sufficient to identify a component in which a failure has occurred in the pin electronics apparatus 110 (for example, a component ID unique in the pin electronics apparatus 110).

In S340, the monitoring circuit 230 records, as the failure information, the power abnormality information including the power identification information on the recording medium 260 before the power supply to the monitoring circuit 230 is cut off. The monitoring circuit 230 may record the failure detection date and time on the recording medium 260 in association with the power abnormality information.

The monitoring circuit 230 may encrypt at least a part of the failure information and record a result on the recording medium 260. For example, the monitoring circuit 230 may encrypt at least one of the power identification information included in the failure information, the detailed component information of the failed power circuit 200 or power source 205, the failure type information, or the like. Accordingly, the monitoring circuit 230 can prevent the pin electronics apparatus 110 from being further damaged due to improper component replacement of a third party who is not familiar with the pin electronics apparatus 110.

After the power supply from the power circuit 200 is cut off, in S350, the recording medium 260 is read by near field communication or the like without the power supply from the power circuit 200. Note that, for example, when there is a power abnormality to such an extent that the power source 205 which supplies power to the monitoring circuit 230 does not need to be cut off or when the test apparatus 1 is reactivated, the control apparatus 170 may read the recording medium 260 to acquire the failure detection date and time and the failure information.

According to the pin electronics apparatus 110 described above, the recording medium 260 can maintain the written failure information or the like even when the power circuit 200 fails and the power supply from the power circuit 200 is cut off. Therefore, the pin electronics apparatus 110 can provide the failure information or the like to a user such as a maintenance worker of the test apparatus 1 or an external apparatus such as the control apparatus 170 even after shutdown of the test apparatus 1 or power supply cut-off of the power circuit 200.

In addition, since the recording medium 260 records, on the recording medium 260, the failure information including the power identification information for identifying the power source 205 for which the abnormality in power supply has been detected, it is possible to easily specify the failed power source 205 among the plurality of power sources 205. In addition, even when an abnormality occurs intermittently in the power source 205 or when an abnormality occurs in the power source 205 only under a certain condition, the pin electronics apparatus 110 records, on the recording medium 260, the power source 205 for which an abnormality is detected, in an identifiable manner, and thus it is possible to improve repairability, product quality, or mean time to repair (MTTR) of the pin electronics apparatus 110. In addition, by recording the failure detection date and time on the recording medium 260 in association with the failure information, the pin electronics apparatus 110 can provide the user of the test apparatus 1 with information that makes it easier to investigate a cause of a component in the pin electronics apparatus 110, such as a constant failure, an intermittent abnormality, or a temporary abnormality due to external noise such as a lightning strike.

Note that the control apparatus 170 or the pin electronics apparatus 110 may be configured to control the power circuit 200 to cut off the power source of the pin electronics apparatus 110 in a predetermined power cut-off sequence. In this case, in response to detecting the abnormality in power supply, the power circuit 200 cuts off the plurality of power sources 205a to 205d in order of the predetermined power cut-off sequence. In such a configuration, the monitoring circuit 230 may receive the power supply from the power source 205 to be cut off after at least one other power source 205 among the plurality of power sources 205a to 205d is cut off.

For example, when the power circuit 200 cuts off the power supply every 400 ms in order of the power source 205d, the power source 205c, the power source 205b, and the power source 205a, there is a delay of 1200 ms from cut-off of the power supply from the power source 205d to cut-off of the power supply from the power source 205a. By receiving the power supply from the power source 205a, the monitoring circuit 230 can start writing the failure information to the recording medium 260 after start of the cut-off of the power supply and finish writing the failure information before the cut-off of the power supply from the power source 205a. As described above, the monitoring circuit 230 may be configured to receive the power supply from the power source 205 from which the power supply is cut off after the writing of the failure information is completed after detection of the abnormality in the power supply. The monitoring circuit 230 may receive the power supply from the power source 205, which is cut off last in the power cut-off sequence, among the plurality of power sources 205.

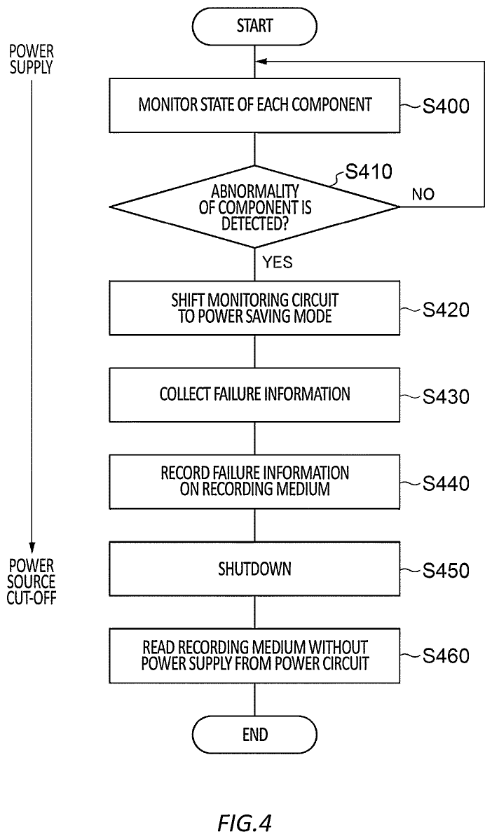

FIG. 4 illustrates a failure monitoring flow of the pin electronics apparatus 110 according to the present embodiment. The pin electronics apparatus 110 starts the failure monitoring flow of this drawing in a state where each circuit in the pin electronics apparatus 110 is operating normally. The pin electronics apparatus 110 may start the failure monitoring flow of this drawing in self-diagnosis performed, for example, when the test apparatus 1 is powered on. Note that, since the failure of the power circuit 200 is a type of failure of components in the pin electronics apparatus 110, the power monitoring flow illustrated in FIG. 3 may be one form or a subset of the failure monitoring flow in this drawing.

In S400, the microcontroller 245 in the monitoring circuit 230 monitors the state of each component in the pin electronics apparatus 110. In S410, the microcontroller 245 determines whether or not an abnormality of the component in the pin electronics apparatus 110 is detected. Each component in the pin electronics apparatus 110 includes various error detectors which detect abnormalities such as parity/ECC errors, queue overflows/underflows, or detections of undefined instructions, for example. In response to receiving an error detection signal indicating that an abnormality has occurred from the error detector, the microcontroller 245 detects the abnormality of the component including the error detector. The microcontroller 245 may detect the abnormality of the component in response to the temperature detection circuit 240 detecting that a temperature of the component exceeds a reference temperature defined for the component.

In addition, in the self-diagnosis of the test apparatus 1, the pin electronics apparatus 110 performs a self-diagnosis test of each internal component. The microcontroller 245 may detect the abnormality of the component according to a result of the self-diagnosis test. The microcontroller 245 acquires, as the failure detection date and time, a date and time which is indicated by the internal clock 246 at a timing when the failure of the pin electronics apparatus 110 is detected.

If all the components are normal, the microcontroller 245 advances the processing to S400 to continue monitoring the state of each component (“NO” in S410). If any of the components is abnormal, the microcontroller 245 advances the processing to S420 (“YES” in S410).

In S420, in response to detecting the abnormality of the component, the monitoring circuit 230 shifts to the power saving mode in which the power consumption is smaller than that in a case of performing the normal operation. For example, the monitoring circuit 230 may reduce the power consumption, for example, by stopping power supply to at least one of the voltage detection circuit 235 or the temperature detection circuit 240, by shifting the microcontroller 245 to the power saving mode to cut off power supply to some circuits in the microcontroller 245, or by reducing the operating frequency of the microcontroller 245. Note that the monitoring circuit 230 may shift to the power saving mode when the power supply to the monitoring circuit 230 is stopped due to occurrence of a severe abnormality, which requires emergency shutdown of the test apparatus 1, such as a power short circuit or a mechanical failure, and may not execute S420 when a minor abnormality that allows the operation of the test apparatus 1 to continue occurs.

In S430, the monitoring circuit 230 collects the failure information. The failure information may include the component identification information, and may include the failure type information, the detailed component information, and various types of information regarding the failure, such as a state value of each component or a failed component, or internal data.

In S440, the monitoring circuit 230 records the failure information on the recording medium 260 before the power supply to the monitoring circuit 230 is cut off. The monitoring circuit 230 may record the failure detection date and time in the recording medium 260 in association with the failure information.

The monitoring circuit 230 may encrypt at least a part of the failure information and record a result on the recording medium 260. For example, the monitoring circuit 230 may encrypt at least one of the component identification information for identifying the failed component, the detailed component information of the failed component, the failure type information, or the like.

When a severe abnormality occurs, the test apparatus 1 is shut down in S450. Thus, the power circuit 200 in the pin electronics apparatus 110 stops the power supply to each circuit in the pin electronics apparatus 110. After the power supply from the power circuit 200 is stopped, in S460, the recording medium 260 is read by near field communication or the like without the power supply from the power circuit 200. For example, when there is a power abnormality to such an extent that the power source 205 which supplies power to the monitoring circuit 230 does not need to be cut off or when the test apparatus 1 is reactivated, the control apparatus 170 may read the recording medium 260 to acquire the failure detection date and time and the failure information.

According to the pin electronics apparatus 110 described above, the recording medium 260 can maintain the written failure information even when a circuit or a component in the pin electronics apparatus 110 fails and the test apparatus 1 is shut down. Therefore, the pin electronics apparatus 110 can provide the failure information to the user of the test apparatus 1 or an external apparatus such as the control apparatus 170 even after the shutdown of the test apparatus 1 or the power supply cut-off of the power circuit 200.

In addition, since the recording medium 260 records, on the recording medium 260, the failure information including the component identification information for identifying the failed component, it is possible to easily specify the failed component among the plurality of components. For example, the ASIC/LSI/IC in the pin electronics apparatus 110 may be attached with a heat sink for cooling or enclosed in a water jacket for liquid cooling. When the recording medium 260 records, as the component identification information, at least one of the product model number, the serial number, the date of manufacture, the manufacturer, or the like of such a component, the user of the test apparatus 1 can obtain the detailed component identification information without removing the heat sink or the like.

In addition, according to the pin electronics apparatus 110 described above, by using, as the recording medium 260, a recording medium which is readable without receiving the power supply from the power circuit 200, the failure information can be provided to the user of the test apparatus 1 or an external apparatus without powering on the pin electronics apparatus 110 even after the shutdown of the test apparatus 1 or the power supply cut-off of the power circuit 200.

Note that the monitoring circuit 230 may write in advance, to the recording medium 260, the component information for each of the plurality of components mounted on the pin electronics apparatus 110, in association with the component identification information, before the detection of the abnormality in the power supply or the failure of the pin electronics apparatus 110. In addition, the monitoring circuit 230 may write in advance, to the recording medium 260, other information that can be written to the recording medium 260 in advance, before the detection of the abnormality in the power supply or the failure of the pin electronics apparatus 110. By writing as much information as possible to the recording medium 260 before the detection of the abnormality in the power supply or the failure of the pin electronics apparatus 110, the monitoring circuit 230 can reduce a size of information to be written to the recording medium 260 after the detection of the abnormality in the power supply or the failure of the pin electronics apparatus 110, and can reduce a duration for writing to the recording medium 260.

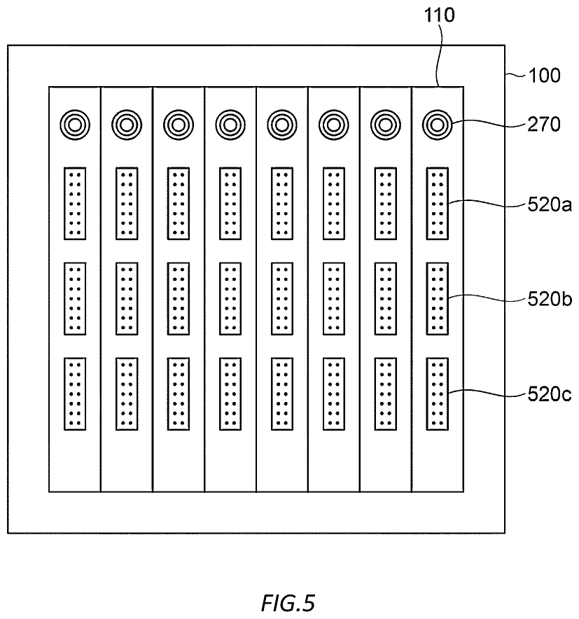

FIG. 5 illustrates a structure of the test head 100 according to the present embodiment as viewed from a mounting surface side of the connection apparatus 120 (an upper surface side of the test head 100 in the test apparatus 1 of FIG. 1). Each of the plurality of pin electronics apparatuses 110 is inserted into the slot of the test head 100, and an edge thereof on a side of the connection apparatus 120 and the DUT 10 is exposed to an outer surface of the test head 100. The pin electronics apparatus 110 includes one or more connectors 520a to 520c (also referred to as a “connector(s) 520”) and the antenna 270 at the edge on the side of the connection apparatus 120 and the DUT 10.

Each connector 520 is connected to a corresponding connector arranged on a surface of the connection apparatus 120 on the test head 100 side. Accordingly, the pin electronics apparatus 110 is electrically connected to the DUT 10 via the connection apparatus 120.

The antenna 270 is provided on an outer surface of the pin electronics apparatus 110, the outer surface being externally exposed in a state where the pin electronics apparatus 110 is mounted on the test head 100. In an example of this drawing, the antenna 270 is provided on an outer surface, on which the connectors 520a to 520c electrically connected to the DUT 10 are equipped, of the pin electronics apparatus 110. Accordingly, by removing the connection apparatus 120 mounted on the test head 100, the antenna 270 is externally exposed without removing the pin electronics apparatus 110 from the test head 100. In this state, the recording medium 260 is readable by near field communication using the antenna 270.

The recording medium 260 can read the failure information by receiving power supply by near field wireless power supply via the antenna 270 from a terminal apparatus that reads the failure information, and supply the failure information to the terminal apparatus by the near field communication via the antenna 270. The recording medium 260 may operate by receiving the power supply from the terminal apparatus by the near field wireless power supply via the antenna 270, and supply the failure information to the terminal apparatus by the near field communication.

Therefore, the user of the test apparatus 1 can read and confirm a failure occurrence date and time and the failure information recorded on the recording medium 260 in each pin electronics apparatus 110, by bringing a terminal carried by the user close to the antenna 270 of each pin electronics apparatus 110. The user can confirm the failure information read from each pin electronics apparatus 110 to specify the pin electronics apparatus 110, in which the abnormality has occurred, from among the plurality of pin electronics apparatuses 110, and can remove the pin electronics apparatus 110, in which the abnormality has occurred, from the test head 100 to inspect or replace the pin electronics apparatus 110.

In addition, the terminal which has read the failure information or the like of the pin electronics apparatus 110 via the antenna 270 may upload the failure information or the like to a server apparatus (for example, a cloud server) on the Internet or an intranet via a wireless communication network. Accordingly, the server apparatus can perform unified management of the failure information or the like of the pin electronics apparatuses 110 mounted on a plurality of test apparatuses 1 installed in various places, and can allow a producer or maintenance provider of the test apparatus 1 to confirm the state of each test apparatus 1.

Note that the recording medium 260 may be readable under control of the microcontroller 245 without receiving the power supply from the power circuit 200. In this case, the microcontroller 245 receives power supply by the near field wireless power supply via the antenna 270 from the terminal apparatus which reads the failure information, and reads the failure information from the recording medium 260. Then, the microcontroller 245 supplies the failure information to the terminal apparatus by the near field communication via the antenna 270.

More specifically, after the power supply is started and activation is performed, when the power supply from the power circuit 200 is not received and power supply is received by the near field wireless power supply, the microcontroller 245 transitions to a mode of processing an external read request for the recording medium 260. In this mode, in response to receiving, via the antenna 270, the read request for the recording medium 260, the microcontroller 245 reads requested information (data) from the recording medium 260 and returns the information by the near field communication via the antenna 270.

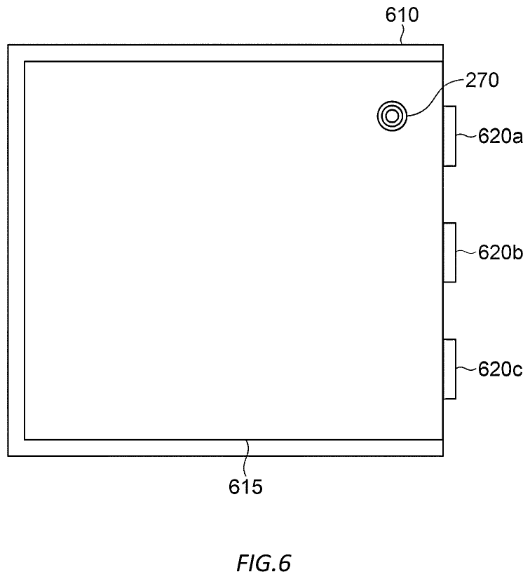

FIG. 6 illustrates a structure of a pin electronics apparatus 610 according to a first modification. The test apparatus 1 may include the pin electronics apparatus 610 instead of the pin electronics apparatus 110 illustrated in FIGS. 1 to 5. Since the pin electronics apparatus 610 is a modification of the pin electronics apparatus 110, description thereof will be omitted below except for differences.

The pin electronics apparatus 610 includes a main board 615 and one or more connectors 620a to 620c (also referred to as a “connector(s) 620”). The main board 615 is equipped with each circuit and each component illustrated in FIG. 2. This drawing illustrates the structure of the pin electronics apparatus 610 when the pin electronics apparatus 610 is viewed from a component equipping surface side of the main board 615. Here, the component equipping surface side of the pin electronics apparatus 610 is an upper surface side when the pin electronics apparatus 610 taken out from the test head 100 is placed on a desk or the like. The antenna 270 is provided in a side portion, on which the one or more connectors 620 connected to the DUT 10 are equipped, of an upper surface of the pin electronics apparatus 610. The antenna 270 may be provided in a corner of the upper surface of the pin electronics apparatus 610 on a side on which the one or more connectors 620 are equipped. Since the one or more connectors 620 are similar to the one or more connectors 520 illustrated in FIG. 5, description thereof will be omitted.

Since the pin electronics apparatus 610 has the antenna 270 in the side portion, on which each connector 620 is equipped, of the upper surface, it is possible to enable the recording medium 260 to be read by the near field communication using the antenna 270 without bringing the terminal close to a central portion or the like where the circuits in the pin electronics apparatus 610 are densely equipped. Accordingly, the pin electronics apparatus 610 can reduce a risk of damage to the pin electronics apparatus 610 due to the terminal falling or the like.

In addition, the main board 615 may have a structure in which wiring is concentrated on each connector 620 in the side portion on which each connector 620 is equipped, and a region having no wiring pattern is easily secured outside a vicinity of each connector 620. In such a case, the main board 615 has an antenna pattern of the antenna 270 in the side portion on which each connector 620 is equipped, so that it is possible to prevent other wiring patterns from being included in a layer provided with the antenna 270 and upper and lower layers thereof and to suppress interference with the near field communication. Note that depending on arrangement of components or wiring patterns of the main board 615, the antenna 270 may be provided at another location on the upper surface of the pin electronics apparatus 110.

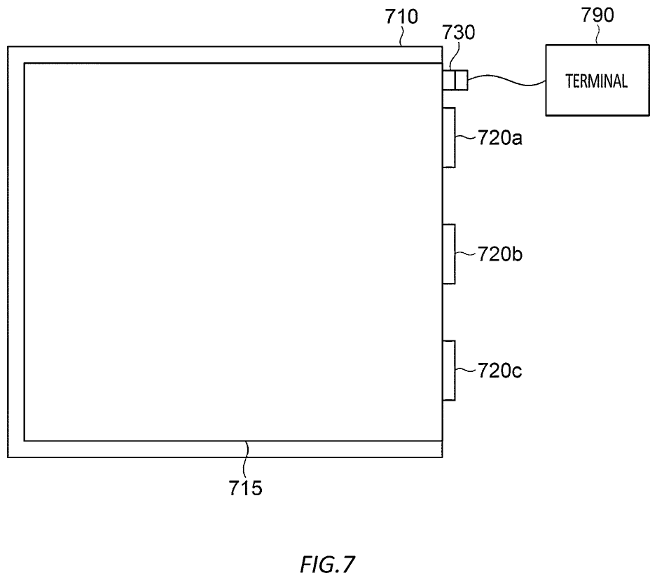

FIG. 7 illustrates a structure of a pin electronics apparatus 710 according to a second modification. The test apparatus 1 may include the pin electronics apparatus 710 instead of the pin electronics apparatus 110 illustrated in FIGS. 1 to 5 and the pin electronics apparatus 610 illustrated in FIG. 6. Since the pin electronics apparatus 710 is a modification of the pin electronics apparatus 110 and the pin electronics apparatus 610, description thereof will be omitted below except for differences.

The pin electronics apparatus 710 includes a main board 715 and one or more connectors 720a to 720c (also referred to as a “connector(s) 720”) and a monitoring connector 730. The main board 715 is equipped with each circuit and each component illustrated in FIG. 2. This drawing illustrates the structure of the pin electronics apparatus 710 when the pin electronics apparatus 710 is viewed from a component equipping surface side of the main board 715. Here, the component equipping surface side of the pin electronics apparatus 710 is an upper surface side when the pin electronics apparatus 710 taken out from the test head 100 is placed on a desk or the like. Since the one or more connectors 720 are similar to the one or more connectors 520 illustrated in FIG. 5 or the one or more connectors 620 illustrated in FIG. 6, description thereof will be omitted.

The monitoring connector 730 is provided instead of the antenna 270, and is used to connect a terminal 790, which reads the failure information, to the recording medium 260 in a wired manner. The recording medium 260 may receive power supply from the terminal 790 via the monitoring connector 730. The recording medium 260 reads the failure information in response to a read request from the terminal 790, and supplies the failure information to the terminal 790 by wired communication via the monitoring connector 730.

The monitoring connector 730 may be provided on an outer surface, on which the connectors 720a to 720c electrically connected to the DUT 10 are equipped, of the pin electronics apparatus 710. Accordingly, by removing the connection apparatus 120 mounted on the test head 100, the monitoring connector 730 is externally exposed without removing the pin electronics apparatus 110 from the test head 100. In this state, the recording medium 260 is readable by wired communication using the monitoring connector 730.

Alternatively, the monitoring connector 730 may be provided in a side portion, on which the one or more connectors 720 connected to the DUT 10 are equipped, of the upper surface of the pin electronics apparatus 710 or the like. In this case, the monitoring connector 730 becomes accessible in a state where the pin electronics apparatus 710 is removed from the test head 100 and placed on a desk or the like.

Note that the recording medium 260 may be readable under the control of the microcontroller 245 without receiving the power supply from the power circuit 200. In this case, the microcontroller 245 receives power supply from the terminal 790 via the monitoring connector 730, and reads the failure information from the recording medium 260. Then, the microcontroller 245 supplies the failure information to the terminal apparatus via the monitoring connector 730.

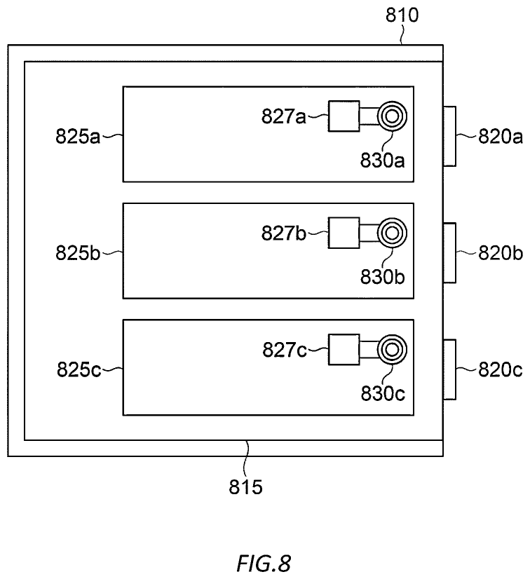

FIG. 8 illustrates a structure of a pin electronics apparatus 810 according to a third modification. The test apparatus 1 may include the pin electronics apparatus 810 instead of the pin electronics apparatus 110 illustrated in FIGS. 1 to 5, the pin electronics apparatus 610 illustrated in FIG. 6, and the pin electronics apparatus 710 illustrated in FIG. 7. Since the pin electronics apparatus 810 is a modification of the pin electronics apparatus 110, the pin electronics apparatus 610, and the pin electronics apparatus 710, description thereof will be omitted below except for differences.

The pin electronics apparatus 810 includes a main board 815, one or more sub boards 825a to 825c (also referred to as a “sub board(s) 825”), and one or more connectors 820a to 820c (also referred to as a “connector(s) 820”). The main board 815 is mounted with the one or more sub boards 825. This drawing illustrates the structure of the pin electronics apparatus 810 when the pin electronics apparatus 810 is viewed from a surface side of the main board 815 where the sub board 825 is mounted. Here, the surface side of the main board 815 where the sub board 825 is mounted is an upper surface side when the pin electronics apparatus 810 taken out from the test head 100 is placed on a desk or the like.

The one or more sub boards 825 are mounted on the main board 815. Each sub board 825 may be equipped with each circuit or component included in the pin electronics apparatus 110 illustrated in FIG. 2. Accordingly, in the one or more sub boards 825, a monitoring circuit 827 and an antenna 830 may be mounted on each sub board 825. Therefore, the pin electronics apparatus 810 includes one or more monitoring circuits 827a to 827c (also referred to as a “monitoring circuit(s) 827″), each mounted on the corresponding sub board 825, and one or more antennas 830a to 830c (also referred to as an “antenna(s) 830”). Here, each monitoring circuit 827 may have a function and a configuration similar to those of the monitoring circuit 230 illustrated in FIG. 1. In addition, each antenna 830 may have a function and a configuration similar to those of the antenna 270 illustrated in FIG. 1.

By providing the monitoring circuit 827 and the antenna 830 on each sub board 825, the pin electronics apparatus 810 can read the failure information or the like recorded on the recording medium 260 mounted on each of the one or more sub boards 825 by the near field communication. Therefore, the user of the test apparatus 1 can read and confirm the failure occurrence date and time and the failure information recorded on the recording medium 260 in each sub board 825, by bringing the terminal carried by the user close to the antenna 830 of each sub board 825. The user can confirm the failure information read from each sub board 825 to specify the sub board 825, in which the abnormality has occurred, from the one or more sub boards 825, and can remove the sub board 825, in which the abnormality has occurred, from the pin electronics apparatus 810 to inspect or replace the sub board 825.

Various embodiments of the present invention may be described with reference to flowcharts and block diagrams, where blocks may represent (1) stages of processes in which operations are executed or (2) sections of apparatuses responsible for executing operations. Certain stages and sections may be implemented by a dedicated circuit, a programmable circuit supplied together with computer-readable instructions stored on computer-readable media, and/or processors supplied together with computer-readable instructions stored on computer-readable media. The dedicated circuit may include digital and/or analog hardware circuits, and may include integrated circuits (IC) and/or discrete circuits. The programmable circuit may include a reconfigurable hardware circuit including logical AND, logical OR, logical XOR, logical NAND, logical NOR, and other logical operations, a memory element or the like such as a flip-flop, a register, a field programmable gate array (FPGA) and a programmable logic array (PLA), or the like.

A computer-readable medium may include any tangible device that can store instructions to be executed by a suitable device, and as a result, the computer-readable medium having instructions stored thereon includes a product including instructions that can be executed in order to create means for executing operations specified in the flowcharts or block diagrams. Examples of the computer-readable medium may include an electronic storage medium, a magnetic storage medium, an optical storage medium, an electromagnetic storage medium, a semiconductor storage medium, and the like. More specific examples of the computer-readable medium may include a FLOPPY (registered trademark) disk, a diskette, a hard disk, a random access memory (RAM), a read-only memory (ROM), an erasable programmable read-only memory (EPROM or flash memory), an electrically erasable programmable read-only memory (EEPROM), a static random access memory (SRAM), a compact disc read-only memory (CD-ROM), a digital versatile disk (DVD), a BLU-RAY (registered trademark) disk, a memory stick, an integrated circuit card, and the like.

The computer-readable instruction may include: an assembler instruction, an instruction-set-architecture (ISA) instruction; a machine instruction; a machine dependent instruction; a microcode; a firmware instruction; state-setting data; or either a source code or an object code described in any combination of one or more programming languages, including an object oriented programming language such as SMALLTALK (registered trademark), JAVA (registered trademark), C++, or the like, and a conventional procedural programming language such as a “C” programming language or a similar programming language.

The computer-readable instructions may be provided for a processor or programmable circuit of a general purpose computer, special purpose computer, or other programmable data processing apparatuses such as a computer locally or via a wide area network (WAN) such as a local area network (LAN), the Internet, or the like, and execute the computer-readable instructions in order to create means for executing the operations designated in flowcharts or block diagrams. Examples of the processor include a computer processor, a processing unit, a microprocessor, a digital signal processor, a controller, a microcontroller, and the like.

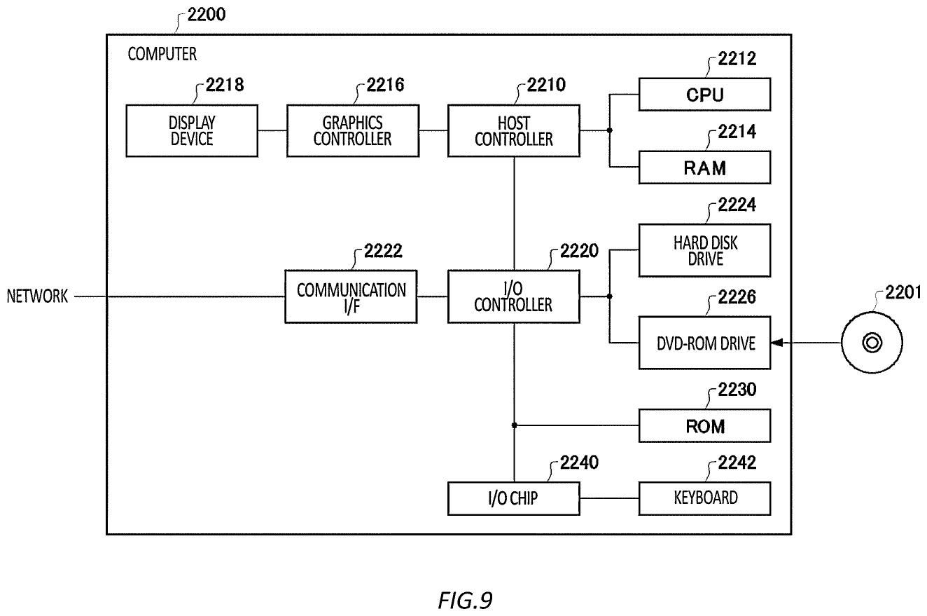

FIG. 9 illustrates an example of a computer 2200 in which a plurality of aspects of the present invention may be embodied entirely or partially. A program installed in the computer 2200 can cause the computer 2200 to function as an operation associated with the apparatuses according to the embodiments of the present disclosure or as one or more sections of the apparatuses, or can cause the operation or the one or more sections to be executed, and/or can cause the computer 2200 to execute a process according to the embodiments of the present disclosure or a stage of the process. Such programs may be executed by a CPU 2212 to cause the computer 2200 to perform specific operations associated with some or all of the blocks in the flowcharts and block diagrams described in the present specification.

The computer 2200 according to the present embodiment includes the CPU 2212, an RAM 2214, a graphics controller 2216, and a display device 2218, which are mutually connected by a host controller 2210. The computer 2200 also includes input/output units such as a communication interface 2222, a hard disk drive 2224, a DVD-ROM drive 2226, and an IC card drive, which are connected to the host controller 2210 via an input/output controller 2220. The computer also includes legacy input/output units such as an ROM 2230 and a keyboard 2242, which are connected to the input/output controller 2220 via an input/output chip 2240.

The CPU 2212 operates according to programs stored in the ROM 2230 and the RAM 2214, thereby controlling each unit. The graphics controller 2216 acquires image data generated by the CPU 2212 in a frame buffer or the like provided in the RAM 2214 or in itself, such that the image data is displayed on the display device 2218.

The communication interface 2222 communicates with other electronic devices via a network. The hard disk drive 2224 stores programs and data used by the CPU 2212 in the computer 2200. The DVD-ROM drive 2226 reads a program or data from a DVD-ROM 2201 and provides the program or data to the hard disk drive 2224 via the RAM 2214. The IC card drive reads the programs and the data from the IC card, and/or writes the programs and the data to the IC card.

The ROM 2230 stores therein boot programs and the like executed by the computer 2200 at the time of activation, and/or programs that depend on the hardware of the computer 2200. The input/output chip 2240 may also connect various input/output units to the input/output controller 2220 via a parallel port, a serial port, a keyboard port, a mouse port, or the like.

The program is provided by a computer-readable medium such as the DVD-ROM 2201 or the IC card. The program is read from a computer-readable medium, installed in the hard disk drive 2224, the RAM 2214, or the ROM 2230 which are also examples of the computer-readable medium, and executed by the CPU 2212. The information processing described in these programs is read by the computer 2200 and provides cooperation between the programs and the above-described various types of hardware resources. The apparatus or method may be configured by implementing operations or processing of information according to use of the computer 2200.

For example, when communication is performed between the computer 2200 and an external device, the CPU 2212 may execute a communication program loaded in the RAM 2214 and instruct the communication interface 2222 to perform communication processing based on processing described in the communication program. Under the control of the CPU 2212, the communication interface 2222 reads transmission data stored in a transmission buffer processing region provided in a recording medium such as the RAM 2214, the hard disk drive 2224, the DVD-ROM 2201, or the IC card, transmits the read transmission data to the network, or writes reception data received from the network in a reception buffer processing region or the like provided on the recording medium.

In addition, the CPU 2212 may cause the RAM 2214 to read all or a necessary part of a file or database stored in an external recording medium such as the hard disk drive 2224, the DVD-ROM drive 2226 (DVD-ROM 2201), the IC card, or the like, and may execute various types of processing on data on the RAM 2214. Then, the CPU 2212 writes the processed data back in the external recording medium.

Various types of information such as various types of programs, data, tables, and databases may be stored in a recording medium and subjected to information processing. The CPU 2212 may execute, on the data read from the RAM 2214, various types of processing including various types of operations, information processing, conditional judgement, conditional branching, unconditional branching, information retrieval/replacement, or the like described throughout the present disclosure and specified by instruction sequences of the programs, and writes the results back to the RAM 2214. In addition, the CPU 2212 may retrieve information in a file, a database, or the like in the recording medium. For example, when a plurality of entries, each having an attribute value of a first attribute associated with an attribute value of a second attribute, is stored in the recording medium, the CPU 2212 may retrieve, out of the plurality of entries, an entry with the attribute value of the first attribute specified that meets a condition, read the attribute value of the second attribute stored in said entry, and thereby acquiring the attribute value of the second attribute associated with the first attribute meeting a predetermined condition.

The programs or software modules described above may be stored in a computer-readable medium on or near the computer 2200. In addition, a recording medium such as a hard disk or an RAM provided in a server system connected to a dedicated communication network or the Internet can be used as a computer-readable medium, thereby providing a program to the computer 2200 via the network.

While the present invention has been described by way of the embodiments, the technical scope of the present invention is not limited to the above-described embodiments. It is apparent to persons skilled in the art that various alterations or improvements can be made to the above described embodiments. It is also apparent from the described scope of the claims that the embodiments to which such alterations or improvements are made can be included in the technical scope of the present invention.

It should be noted that the operations, procedures, steps, stages, or the like of each process performed by an apparatus, system, program, and method shown in the claims, the specification, or the drawings can be performed in any order as long as the order is not indicated by “prior to,” “before,” or the like and as long as the output from a previous process is not used in a later process. Even if the process flow is described using phrases such as “first” or “next” in the claims, the specification, or the drawings for the sake of convenience, it does not necessarily mean that the process must be performed in this order.

### EXPLANATION OF REFERENCES

1: test apparatus;
10: DUT;
100: test head;
110: pin electronics apparatus;
120: connection apparatus;
150: main frame;
160: main power supply apparatus;
170: control apparatus;
200: power circuit;
205a to 205d: power source;
210: test circuit;
220: test control circuit;
230: monitoring circuit;
235: voltage detection circuit;
240: temperature detection circuit;
245: microcontroller;
246: internal clock;
247: clock setting circuit;
248: write circuit;
250: storage battery;
260: recording medium;
270: antenna;
520a to 520c: connector;
610: pin electronics apparatus;
615: main board;
620a to 620c: connector;
710: pin electronics apparatus;
715: main board;
720a to 720c: connector;
730: monitoring connector;
790: terminal;
810: pin electronics apparatus;
815: main board;
820a to 820c: connector;
825a to 825c: sub board;
827a to 827c: monitoring circuit;
830a to 830c: antenna;
2200: computer;
2201: DVD-ROM;
2210: host controller;
2212: CPU;
2214: RAM;
2216: graphics controller;
2218: display device;
2220: input/output controller;
2222: communication interface;
2224: hard disk drive;
2226: DVD-ROM drive;
2230: ROM;
2240: input/output chip; and
2242: keyboard.

What is claimed is:

1. A pin electronics apparatus comprising:
a test circuit which is connected to a device under test and tests the device under test;
a power circuit which includes a plurality of power sources; and
a monitoring circuit which records, in response to detecting an abnormality in power supply from the power circuit, power identification information for identifying a power source, for which an abnormality in power supply is detected, among the plurality of power sources on a non-volatile recording medium.

2. The pin electronics apparatus according to claim 1, wherein in response to detecting an abnormality in power supply from the power circuit, the monitoring circuit records the power identification information on the non-volatile recording medium before power supply to the monitoring circuit is cut off.

3. The pin electronics apparatus according to claim 2, wherein
in response to detecting an abnormality in power supply, the power circuit cuts off the plurality of power sources in order of a predetermined power cut-off sequence, and
the monitoring circuit receives power supply from a power source to be cut off after at least one other power source among the plurality of power sources is cut off.

4. The pin electronics apparatus according to claim 3, wherein the monitoring circuit records the power identification information on the non-volatile recording medium during a period from start of cut-off of the plurality of power sources based on the power cut-off sequence to cut-off of a power source which supplies power to the monitoring circuit.

5. The pin electronics apparatus according to claim 1, further comprising
a storage battery which accumulates power from at least one of the plurality of power sources, wherein
the monitoring circuit records the power identification information on the non-volatile recording medium after cut-off of power supply from the power circuit and before interruption of power supply from the storage battery.

6. The pin electronics apparatus according to claim 5, wherein the storage battery includes a capacitor which accumulates power.

7. The pin electronics apparatus according to claim 5, wherein in response to receiving power supply from the storage battery, the monitoring circuit shifts to a power saving mode in which power consumption is smaller than that in a case of performing a normal operation.

8. The pin electronics apparatus according to claim 1, wherein for each power source of the plurality of power sources, the monitoring circuit detects an abnormality in the power source in response to at least one of a fact that an output voltage of the power source is outside a reference voltage range predetermined for each power source or a fact that a temperature associated with the power source exceeds a predetermined reference temperature.

9. The pin electronics apparatus according to claim 1, wherein the monitoring circuit includes a microcontroller which performs monitoring the plurality of power sources and writing on the non-volatile recording medium by executing a monitoring program.

10. The pin electronics apparatus according to claim 1, wherein the non-volatile recording medium is readable without receiving power supply from the power circuit.

11. The pin electronics apparatus according to claim 10, wherein the non-volatile recording medium is readable by near field communication.

12. The pin electronics apparatus according to claim 11, comprising
an antenna which is provided on an outer surface of the pin electronics apparatus, the outer surface being externally exposed in a state where the pin electronics apparatus is mounted on a test head, wherein
the non-volatile recording medium is readable by near field communication using the antenna.

13. The pin electronics apparatus according to claim 12, wherein the antenna is provided on an outer surface, on which a connector connected to the device under test is equipped, of the pin electronics apparatus.

14. The pin electronics apparatus according to claim 11, comprising
an antenna which is provided on a side portion, on which a connector connected to the device under test is equipped, of an upper surface of the pin electronics apparatus, wherein
the non-volatile recording medium is readable by near field communication using the antenna.

15. A test apparatus comprising:
one or more pin electronics apparatuses including the pin electronics apparatus according to claim 1;
a control apparatus which controls the one or more pin electronics apparatuses; and
a connection apparatus which connects the one or more pin electronics apparatuses to one or more devices under test.

16. A test apparatus comprising:
one or more pin electronics apparatuses including the pin electronics apparatus according to claim 2;
a control apparatus which controls the one or more pin electronics apparatuses; and
a connection apparatus which connects the one or more pin electronics apparatuses to one or more devices under test.

17. A test apparatus comprising:
one or more pin electronics apparatuses including the pin electronics apparatus according to claim 3;
a control apparatus which controls the one or more pin electronics apparatuses; and
a connection apparatus which connects the one or more pin electronics apparatuses to one or more devices under test.

18. A test apparatus comprising:
one or more pin electronics apparatuses including the pin electronics apparatus according to claim 4;
a control apparatus which controls the one or more pin electronics apparatuses; and
a connection apparatus which connects the one or more pin electronics apparatuses to one or more devices under test.

19. A test apparatus comprising:
one or more pin electronics apparatuses including the pin electronics apparatus according to claim 5;
a control apparatus which controls the one or more pin electronics apparatuses; and
a connection apparatus which connects the one or more pin electronics apparatuses to one or more devices under test.

20. A method comprising:
testing, by a pin electronics apparatus connected to a device under test, the device under test; and
in response to detecting an abnormality in power supply from a power circuit including a plurality of power sources, recording, by the pin electronics apparatus, power identification information for identifying a power source, for which an abnormality in power supply is detected, among the plurality of power sources on a non-volatile recording medium.
